(19) United States
(12) Patent Application Publication
(10) Pub. No.: US 2026/0344360 A1
(43) Pub. Date: Oct. 29, 2026

(54) SEMICONDUCTOR PROCESSING CHAMBER COMPONENT WITH A LASER GLAZED METAL OXIDE INTERMEDIATE LAYER

(71) Applicant: Lam Research Corporation, Fremont, CA (US)

(72) Inventors: Jesu Titus IRUDAYARAJ, Bangalore (IN); Eric A. PAPE, Santa Cruz, CA (US)

(21) Appl. No.: 19/490,292

(22) PCT Filed: Jul. 3, 2024
(86) PCT No.: PCT/US2024/036805

§ 371 Date: Dec. 4, 2025

Related U.S. Application Data
(60) Provisional application No. 63/512,726, filed on Jul. 10, 2023.

(51) Int. Cl. H10P 72/76; H10P 72/72

(52) U.S. Cl. CPC H10P 72/7616; H10P 72/722

(57) ABSTRACT

A component for use in a semiconductor processing chamber is provided. The component comprises a metal component body of a first metal, an intermediate layer over the metal component body comprising a laser glazed metal oxide of the first metal, and a ceramic coating over the intermediate layer, wherein the intermediate layer is between the metal component body and the ceramic coating.

### CROSS-REFERENCE TO RELATED APPLICATION

This application claims the benefit of priority of U.S. Application No. 63/512,726, filed Jul. 10, 2023, which is incorporated herein by reference for all purposes.

### BACKGROUND

The disclosure relates to a semiconductor processing chamber for forming semiconductor devices on a semiconductor wafer.

In the formation of semiconductor devices, semiconductor processing chambers are used to process semiconductor devices. The semiconductor processing chamber may use an electrostatic chuck (ESC). The ESC may comprise a metal baseplate bonded to a ceramic plate. The ESC may be subjected to a corrosive plasma environment.

Various components of a semiconductor processing chamber may be subjected to a plasma. The plasma may be an etching plasma that may also erode surfaces of metal components of semiconductor processing chambers. Ceramic coatings may be provided on surfaces of metal components in order to reduce erosion of the metal components. A mismatch in the coefficients of thermal expansion for the metal components and the ceramic coatings may cause a variety of mechanical failure mechanisms, such as delamination, decohesion, spallation, cracking, and grazing.

The background description provided here is for the purpose of generally presenting the context of the disclosure. The information described in this background section, as well as aspects of the description that may not otherwise qualify as prior art at the time of filing, are neither expressly nor impliedly admitted as prior art against the present disclosure.

### SUMMARY

To achieve the foregoing and in accordance with the purpose of the present disclosure, a component for use in a semiconductor processing chamber is provided. The component comprises a metal component body of a first metal, an intermediate layer over the metal component body comprising a laser glazed metal oxide of the first metal, and a ceramic coating over the intermediate layer, wherein the intermediate layer is between the metal component body and the ceramic coating.

In another manifestation, a method for forming a component for use in a semiconductor processing chamber is provided. A metal component body is provided. At least one surface of the metal component body is anodized forming an anodized layer. At least part ofthe anodized layer is laser glazed. A ceramic coating is deposited over the anodized layer.

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a flow chart of a process used in some embodiments.

FIGS. 2A-F are cross-sectional views of a component provided in some embodiments.

FIG. 3 is an enlarged view of region A in FIG. 2C according to an embodiment.

FIG. 4 is an enlarged view of region A in FIG. 2C according to another embodiment.

FIG. 5 is an enlarged view of region A in FIG. 2C according to another embodiment.

FIG. 6 is a schematic view of a plasma processing chamber that may employ some embodiments.

In the drawings, like reference numerals are sometimes used to designate like structural elements. It should also be appreciated that the depictions in the figures are diagrammatic and not to scale.

### DETAILED DESCRIPTION OF THE PREFERRED EMBODIMENTS

The present disclosure will now be described in detail with reference to a few preferred embodiments thereof as illustrated in the accompanying drawings. In the following description, numerous specific details are set forth to provide a thorough understanding of the present disclosure. It will be apparent, however, to one skilled in the art, that the present disclosure may be practiced without some or all of these specific details. In other instances, well known process steps and/or structures have not been described in detail to not unnecessarily obscure the present disclosure.

Within etch or deposition semiconductor processing chambers, wafers are generally held in place via an electrostatic chuck (ESC), such as a pedestal system. The ESC may comprise an electrically conductive baseplate, a ceramic plate, and a bond layer bonding the baseplate to the ceramic plate.

The metal parts of an ESC can be subjected to large voltages as compared to the chamber body. In addition, the metal parts of the ESC may be subjected to chemical and plasma degradation. There is a need to protect the metal parts of ESCs from chemical and plasma degradation and electrical discharge.

Ceramic coatings may be provided on surfaces of metal components in order to reduce erosion of the metal components. A mismatch in the coefficients of thermal expansion for the metal components and the ceramic coatings may cause a variety of mechanical failure mechanisms, such as delamination, decohesion, spallation, cracking, and grazing. Various embodiments increase the adhesion between the ceramic coating and the metal components. Thinner coatings may provide less protection. Thicker coatings may be more subject to mechanical failure or imperfections. Some component manufacturing processes or semiconductor processes are performed at extremely high temperatures and/or extremely low cryo temperatures. The temperature extremes cause additional residual stresses and mechanical failures.

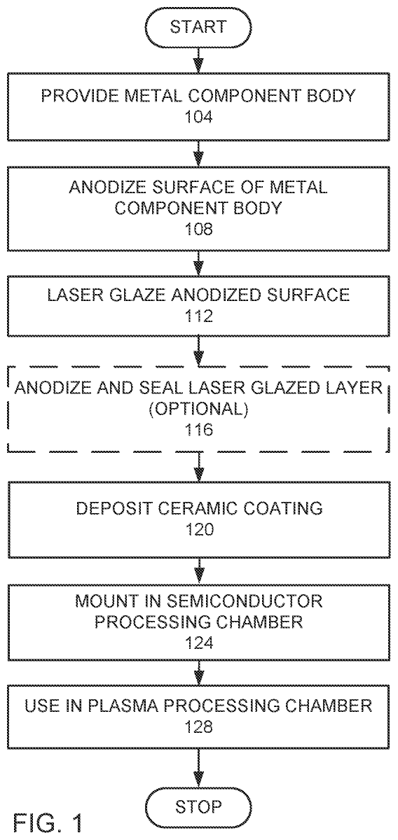

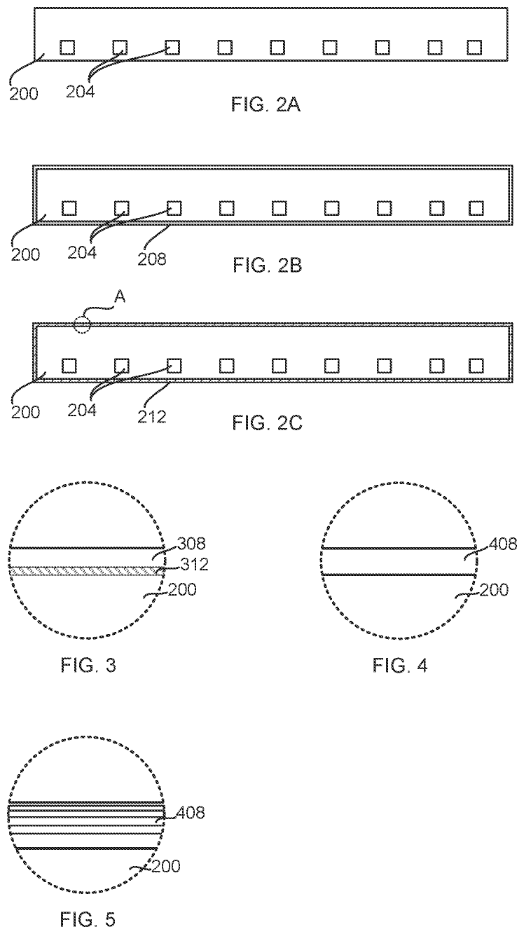

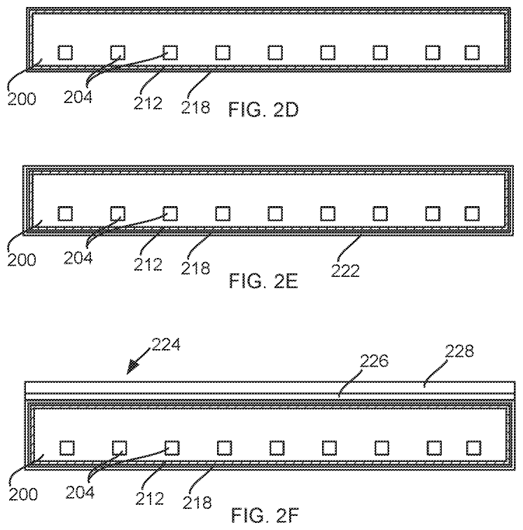

FIG. 1 is a flow chart of methods that may be used in some embodiments. A metal component body is provided (step 104). In some embodiments, the metal component body is a baseplate of an ESC. FIG. 2A is a schematic cross-sectional view of a component body 200 that is a baseplate of an ESC according to some embodiments. In some embodiments, the component body 200 is aluminum. In some embodiments, the aluminum component body 200 is made of an aluminum alloy, such as aluminum 6061. In some embodiments, the component body 200 has temperature control channels 204 for providing a flow of a temperature control fluid.

Next, a surface anodization of the surface of the component body is provided (step 108). In some embodiments, a Type I anodization of aluminum 6061 is used to provide an anodized aluminum layer with a thickness in the range of 5 μm to 15 μm. The Type I anodization process is a process where an aluminum component body is subjected to a chromic acid bath to provide a thin anodic layer. In some embodiments, a Type III anodization process is used to anodize the surface of the component body. The Type III anodization process (also referred to as hard anodization or hard-coat anodization) is a process where an aluminum component body is subjected to a sulfuric bath at a temperature of 0 °C to 3 °C and high voltage (up to 100V) to create the oxide or “anodized” layer. In some embodiments, the Type III anodized layer has a thickness in the range of 25 μm to 125 μm. In other embodiments, a Type II anodization process is used to anodize the surface of the component body. The Type II anodization process is where the surface of the component body is placed in a sulfuric bath at about 20 °C to 25 °C to form an aluminum oxide anodized layer on the surface as well as a depth into the aluminum material. In some embodiments, the Type II anodized layer has a thickness in the range of 15 μm to 30 μm. In some embodiments, the anodized layer is sealed. In some embodiments, the anodized layer is unsealed.

FIG. 2B is a schematic cross-sectional view of the component body 200 after an anodized layer 208 has been formed (step 108). The drawing is not to scale in order to better illustrate the anodized layer 208.

Next, the anodized layer 208 is laser glazed (step 112) forming a laser glazed layer. In some embodiments, the laser is a continuous high-energy laser beam that is scanned across the surface of the anodized layer 208. In some embodiments, the laser beam is provided by a continuous wave (CW) carbon dioxide (CO₂) laser with power in the range of 100 watts (W) to 1,300 W. In some embodiments, the laser beam is provided by a continuous wave CO₂ laser with power in the range of 800 W to 1,300 W. In some embodiments, the laser beam is provided by a continuous wave CO₂ laser with power in the range of 900 W to 1,000 W. In some embodiments, a scanning rate is in the range of 20 millimeters per second (mm/s) to 40 mm/s. The laser power and scanning speed combination allows for the melting of the anodized layer 208 with limited surface evaporation and sputtering and limited creation of defects or surface craters. In some embodiments, the laser beam has a full width at half maximum (FWHM) in the range of 1-10 mm. In some embodiments, the laser beam has a FWHM in the range of 3-6 mm. In some embodiments, the laser glazing transforms some gamma phase aluminum oxide to alpha phase aluminum oxide. In some embodiments, the laser glazing is to a depth that is less than the thickness of the anodized layer 208. In some embodiments, the laser glazing laser glazes at least 70% of the thickness of the anodized layer 208 forming laser glazed alumina.

FIG. 2C is a schematic cross-sectional view of the component body 200 after the anodized layer 208, shown in FIG. 2B, has been laser glazed (step 112) to form a laser glazed anodized layer 212. In some embodiments, the anodized layer 208 is formed as a columnar gamma aluminum oxide structure. In some embodiments, the anodized layer 208 is more than 50% gamma phase aluminum oxide by weight. In some embodiments, the laser glazed anodized layer 212 is more than 50% alpha phase aluminum oxide by weight. In some embodiments, the laser glazed anodized layer 212 is more than 90% alpha phase aluminum oxide by weight. In some embodiments, the glazed aluminum oxide is less porous and more dense than the anodized layer 208. FIG. 3 is an enlarged view of region A in FIG. 2C, where the laser gazing is to a depth of less than the thickness of the anodized layer 208. FIG. 3 shows a laser glazed layer 308 over a remaining anodized layer 312 over the component body 200. The laser glazed layer 308 is more chemically resistant and has a lower porosity than the anodized layer 208.

FIG. 4 is an enlarged view of region A in FIG. 2C, where the laser gazing is to a depth equal to the thickness of the anodized layer 208. FIG. 4 shows a laser glazed layer 408 over the component body 200. In some embodiments, the laser glazed layer 408 is more than 50% alpha phase aluminum oxide by weight. In some embodiments, the laser glazed layer 308 is more than 90% alpha phase aluminum oxide by weight.

FIG. 5 is an enlarged view of region A in FIG. 2C, where the laser gazing is to a depth greater than the thickness of the anodized layer 208. FIG. 5 shows a laser glazed layer 508 over the component body 200. Since the laser glazing is to a depth greater than the thickness of the anodized layer, in some embodiments, the resulting laser glazed layer 508 is an intermix of the metal oxide of the anodized layer and the metal of the component body 200. In some embodiments, the glazing causes convective intermixing. In some embodiments, the laser glaze layer 508 is an intermix of aluminum oxide and aluminum (Al₂O₃/Al). In some embodiments, the intermix comprises two discrete phases of a metal and a metal oxide that are intermixed. In some embodiments, the intermix of metal oxide and metal forms a metal matrix composite (MMC). The intermix of aluminum oxide and aluminum has a coefficient of thermal expansion (CTE) between the CTE of aluminum and the CTE of aluminum oxide. In some embodiments, the laser glazed layer 508 has a gradient with the highest concentration of metal oxide near the surface and the lowest concentration of metal near the surface, and the lowest concentration of metal oxide and the highest concentration of metal away from the surface at the final depth of the laser glazing. In some embodiments, the laser glazed layer 508 has a uniform concentration. In some embodiments, the aluminum oxide in the laser glazed layer 508 is more than 50% alpha phase aluminum oxide by weight. In some embodiments, the aluminum oxide in the laser glazed layer 508 is more than 90% alpha phase aluminum oxide by weight. In some embodiments, the formation of the laser glazed layer 508 at a depth greater than the thickness of the anodized layer replaces the anodized layer with an intermix layer.

In some embodiments, the laser glazed anodized layer 212 is further anodized (step 116). In some embodiments, the aluminum of the intermixed aluminum oxide/aluminum layer is anodized. In some embodiments, the anodized laser glazed layer is sealed. In some embodiments, the anodized laser glazed layer is not sealed. In some embodiments, the laser glazed layer is not anodized. FIG. 2D is a schematic cross-sectional view of the component body 200 after the surface of the laser glazed anodized layer 212 has been anodized and sealed to form an anodized laser glazed layer 218 (step 116). In some embodiments, the anodized laser glazed layer 218 is an unsealed anodized laser glazed layer 218.

Next, a ceramic coating is deposited on the component body 200. In some embodiments, the ceramic coating is deposited by at least one of thermal spraying, high velocity oxygen fuel coating, and low velocity oxygen fuel coating. An example of a thermal spray process is a plasma spray process, such as an atmospheric plasma spray (APS) or a suspension plasma spraying (SPS). Atmospheric plasma spraying is a type of thermal spraying in which a torch is formed by applying an electrical potential between two electrodes, leading to the ionization of an accelerated gas (plasma). Torches of this type can readily reach temperatures of thousands of degrees Celsius, liquefying high melting point materials such as ceramics. Ceramic particles are injected into the jet, melted, and then accelerated towards the component body 200 so that the molten or plasticized material coats the surface of the component and cools, forming a solid, conformal coating. In some embodiments, the thermal spraying provides a layer with a thickness in the range of 10 μm to more than 1000 μm. In some embodiments, the ceramic coating comprises a metal oxide. In some embodiments, the ceramic coating comprises at least one of a metal oxide, a metal oxyfluoride, and a metal fluoride. In some embodiments, the ceramic coating comprises at least one of ceramic aluminum oxide (also called alumina), yttrium oxide (also called yttria), magnesium aluminum oxide (MgAl₂O₄) (spinel), and yttrium aluminum garnet (also called YAG). In some embodiments, the ceramic coating has a thickness in the range of 100 μm and 600 μm.

FIG. 2E is a schematic cross-sectional view of the component body 200 after a ceramic coating 222 has been deposited (step 120). In some embodiments with a sealed anodized layer, the ceramic coating 222 is placed on the sealed anodized layer. In some embodiments without a sealed anodized layer, the ceramic coating 222 is placed directly on the laser glazed anodized layer 212. In the various embodiments, the laser glazed anodized layer 212 is an intermediate layer, where the intermediate layer is a laser glazed anodized layer or an intermix layer of metal oxide and metal formed by laser glazing.

Next, the component body 200 is mounted in a semiconductor processing chamber (step 124). In some embodiments, the component body 200 is assembled with other parts to form the ESC. In some embodiments, a ceramic plate is bonded to the component body 200 by a bonding layer to form the ESC. FIG. 2F is a schematic cross-sectional view of the component body 200 bonded by a bond layer 226 to a ceramic plate 228 to form an ESC 224 that may be provided in some embodiments. In some embodiments, the ceramic plate 228 comprises ceramic alumina.

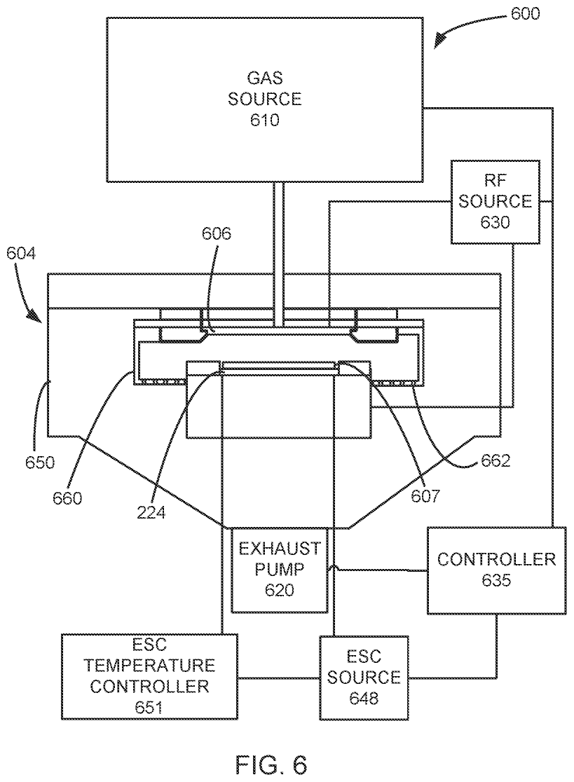

FIG. 6 is a schematic view of a semiconductor processing system 600 for plasma processing substrates, where an embodiment may be installed. In some embodiments, the semiconductor processing system 600 comprises a gas distribution plate 606 providing a gas inlet and the ESC 224, within a semiconductor processing chamber 604, enclosed by a chamber wall 650. Within the semiconductor processing chamber 604, a substrate 607 is positioned on top of the ESC 224. The ESC 224 acts as a substrate support and may provide a bias from an ESC power source 648. A gas source 610 is connected to the semiconductor processing chamber 604 through the gas distribution plate 606. An ESC temperature controller 651 is connected to the ESC 224 and provides temperature control of the ESC 224. A radio frequency (RF) power source 630 provides RF power to the ESC 224 and an upper electrode. In this embodiment, the upper electrode is the gas distribution plate 606. In a preferred embodiment, 13.56 megahertz (MHz), 2 MHz, 60 MHz, and/or optionally, 27 MHz power sources make up the RF power source 630 and the ESC power source 648. A controller 635 is controllably connected to the RF power source 630, the ESC power source 648, an exhaust pump 620, and the gas source 610. A high flow liner 660 is a liner within the semiconductor processing chamber 604. The high flow liner 660 confines gas from the gas source and has slots 662. The slots 662 maintain a controlled flow of gas to pass from the gas source 610 to the exhaust pump 620. An example of such a semiconductor processing chamber is the Exelan Flex™ etch system manufactured by Lam Research Corporation of Fremont, CA. The process chamber can be a CCP (capacitively coupled plasma) reactor or an ICP (inductively coupled plasma) reactor.

The semiconductor processing chamber 604 is used to process a plurality of wafers (step 128). The semiconductor processing may be one or more processes of etching, depositing, passivating, or another process. The semiconductor processing may be at least one of a plasma process and a non-plasma process. Such processes may expose the ESC 224 to plasmas containing halogen and/or oxygen chemistries. In some embodiments, a plurality of wafers is serially or sequentially processed, where a wafer is placed on the ESC 224 and processed and then removed so that another wafer may be placed on the ESC 224 and processed. As a result, the component, such as the ESC 224, is exposed to hundreds or thousands of hours of plasma processes.

In some embodiments, the laser glazed anodized aluminum to an alpha phase aluminum oxide. In some embodiments, the laser glazed anodized aluminum is at least 95% by mass alpha phase aluminum oxide measured by XRD (X-ray diffractometry). In some embodiments, the laser glazed anodized aluminum is at least 90% or 80% by mass alpha phase aluminum oxide measured by XRD. In some embodiments, laser glazed anodized aluminum has a nano hardness in the range of 6500 to 7000 megapascals (MPa).

In some embodiments, the glazed anodized layer provides increased mechanical adhesion and reduced mechanical failure between the ceramic layer and the metal component body. Since embodiments that provide an intermix layer of metal and metal oxide have a CTE between the metal and metal oxide, the intermix layer provides a transition layer between the metal and metal oxide which minimizes CTE mismatch and causes a reduction in delamination. Providing an anodization of the intermix layer forms a metal oxide layer over the intermix layer that provides a protective layer over the intermix layer while providing a layer that will have a CTE close to the metal oxide ceramic layer deposited on the anodized layer. Some embodiments provide a bond coat layer for a metal to metal oxide coating. The anodized layer is molecularly bonded to the surface of the metal component body providing good adhesion between the anodized layer and the metal component body.

In some embodiments, the anodized layer 208 has a thickness in the range of 5 μm to 50 μm. In some embodiments, the laser provides a melting depth in the range of 20 μm to 30 μm. In some embodiments, the laser causes 3 μm to 5 μm of the depth of the metal component body to be melted and intermixed with the anodized layer. In some embodiments, the anodized layer is on the order of 50 μm and the laser glazing reaches a depth of 150 μm to 200 μm so that a depth of 100 μm to 150 μm of the metal component body is melted and intermixed with the anodized layer. In some embodiments, the laser glazing increases the hardness of the anodized layer by 1.5 to 2 times. In some embodiments, laser glazing reduces residual stress from the range of 300 to 350 megapascals (MPa) to 100 to 120 MPa. In addition, in some embodiments, the laser glazing increases the nano hardness of the anodized layer from 3000 MPa to the range of 6500 MPa to 7000 MPa, so that the nano hardness is increased from 1.75 to more than 2 times. In addition, in some embodiments, the laser glazing increases the Young's Modulus of the anodized layer by about 1.5 times from 80 MPa to 100 MPa to 120 MPa. In some embodiments, the corrosion rate of the laser glazed anodized layer is less than half the corrosion rate of the anodized layer. In some embodiments, the coefficient of friction of the laser glazed anodized layer is reduced by 25% compared to the coefficient of friction of the anodized layer. In some embodiments, the wear resistance of the laser glazed anodized layer is improved by at least 50% over the anodized layer. In addition, some embodiments use materials that are not contaminants for semiconductor processing. For example, some embodiments are nickel free, since nickel is a contaminant for semiconductor processes.

In other embodiments, other components of semiconductor processing systems with metal bodies that are exposed to plasma may be provided. Plasma facing surfaces of the components may have a plasma spray ceramic coating. The surface of the ceramic coating may be a laser glazed ceramic coating. In some embodiments, the components are gas distribution plates, showerheads, liners, and electrostatic chucks. Some embodiments are directly applicable to the production of semiconductor components, where cryogenic operating temperatures may cause coating decohesion. Experimental results have shown that the intermediate layer provides an improved bonding at cryogenic temperatures.

In some embodiments, the metal component body comprises a first metal and the intermediate layer comprises a glazed metal oxide comprising the first metal. For example, in some embodiments, the first metal is aluminum, so that the metal component body is aluminum or aluminum alloy and the glazed metal oxide is a glazed anodized aluminum (alumina).

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure. As used herein, the phrase “A, B, or C” should be construed to mean a logical (“A OR B OR C”), using a non-exclusive logical “OR,” and should not be construed to mean ‘only one of A or B or C. Each step within a process may be an optional step and is not required. Different embodiments may have one or more steps removed or may provide steps in a different order. In addition, various embodiments may provide different steps simultaneously instead of sequentially.

What is claimed is:

1. A component for use in a semiconductor processing chamber, the component comprising:
a metal component body of a first metal;
an intermediate layer over the metal component body comprising a laser glazed metal oxide of the first metal; and
a ceramic coating over the intermediate layer, wherein the intermediate layer is between the metal component body and the ceramic coating.

2. The component, as recited in claim 1, wherein the first metal comprises at least one of aluminum and an aluminum alloy and the laser glazed metal oxide comprises glazed alumina.

3. The component, as recited in claim 2, wherein at least 50% of the glazed alumina is in alpha phase.

4. The component, as recited in claim 2, wherein the intermediate layer is at least 70% laser glazed alumina by weight.

5. The component, as recited in claim 2, further comprising an anodized aluminum layer between the intermediate layer and the ceramic coating.

6. The component, as recited in claim 2, further comprising an anodized aluminum layer between the metal component body and the intermediate layer.

7. The component, as recited in claim 2, wherein the intermediate layer comprises an intermix layer of aluminum and laser glazed alumina.

8. The component, as recited in claim 7, further comprising at least one anodized aluminum layer wherein the at least one anodized aluminum layer is above the intermix layer.

9. The component, as recited in claim 2, wherein the component is free of an anodized aluminum layer.

10. The component, as recited in claim 1, wherein the ceramic coating comprises at least one of yttria, aluminum oxide, magnesium aluminum oxide, and yttrium aluminum garnet.

11. The component, as recited in claim 1, wherein the component is part of at least one of an electrostatic chuck, gas distribution plate, showerhead, and liner.

12. A method for forming a component for use in a semiconductor processing chamber, comprising:
providing a metal component body;
anodizing at least one surface of the metal component body forming an anodized layer;
laser glazing at least part of the anodized layer; and
depositing a ceramic coating over the anodized layer.

13. The method, as recited in claim 12, further comprising providing an anodization after the laser glazing and before depositing the ceramic coating.

14. The method, as recited in claim 13, further comprising providing an anodization sealing after providing the anodization after laser glazing.

15. The method, as recited in claim 12, further comprising:
mounting the component in a semiconductor processing chamber; and
using the semiconductor processing chamber for serially processing a plurality of wafers while the component is mounted in the semiconductor processing chamber, wherein the serially processing of the plurality of wafers exposes the component to a plasma.

16. The method, as recited in claim 12, wherein the laser glazing reaches a depth greater than a thickness of the anodized layer causing intermixing of the anodized layer and part of the metal component body.

17. The method, as recited in claim 12, wherein the laser glazing reaches a depth that is less than a thickness of the anodized layer.

18. The method, as recited in claim 12, wherein the depositing the ceramic coating deposits by at least one of thermal spraying, high velocity oxygen fuel coating, low velocity oxygen fuel coating, atmospheric plasma spraying, and suspension plasma spraying.
